(19) United States
(12) Patent Application Publication
(10) Pub. No.: US 2024/0321634 A1
(43) Pub. Date: Sep. 26, 2024

(54) TRANSISTOR AND METHOD FOR MANUFACTURING TRANSISTOR

(71) Applicant: Sumitomo Electric Industries, Ltd., Osaka-shi (JP)

(72) Inventor: Yukihiro TSUJI, Osaka-shi (JP)

(73) Assignee: Sumitomo Electric Industries, Ltd., Osaka-shi (JP)

(21) Appl. No.: 18/606,424

(22) Filed: Mar. 15, 2024

(30) Foreign Application Priority Data
Mar. 22, 2023 (JP) 2023-045684

(51) Int. Cl. H01L 21/768; H01L 23/522; H01L 29/45; H01L 29/47; H01L 29/66; H01L 29/778

(52) U.S. Cl. CPC H01L 21/76876; H01L 21/76879; H01L 23/5226; H01L 29/452; H01L 29/475; H01L 29/66462; H01L 29/7786

(57) ABSTRACT

A transistor includes a semiconductor stack portion, a source electrode, a drain electrode, a gate electrode, a first polysilicon film, a dielectric layer, a first plug, and a first wiring. The source electrode and the drain electrode are provided on the semiconductor stack portion. The gate electrode is provided between the source electrode and the drain electrode on the semiconductor stack portion. The first polysilicon film is provided on a first electrode that is one of the gate electrode, the source electrode, and the drain electrode. The dielectric layer is provided on the semiconductor stack portion and covers the gate electrode, the source electrode, the drain electrode, and the first polysilicon film. The dielectric layer has a first opening formed on the first polysilicon film. The first plug contains tungsten, is embedded in the first opening, and is in contact with the first polysilicon film.

### TECHNICAL FIELD

The present disclosure relates to a transistor and a method for manufacturing a transistor. Priority is claimed on Japanese Patent Application No. 2023-045684, filed Mar. 22, 2023, the content of which is incorporated herein by reference.

### BACKGROUND

Japanese Unexamined Patent Publication No. 2017-069565 (Patent Literature 1) discloses a high electron mobility transistor (HEMT). “Innovative Manufacturing Technology in Semiconductor and Display Industry (Part 1), Technology Alliance Group Co., Ltd., p. 155” (Non Patent Literature 1) discloses semiconductor process technology. Hitoshi Itoh et al., “Mechanism for Initial Stage of Selective Tungsten Growth Employing a WF₆ and SiH₄ Mixture”, Japanese Journal of Applied Physics, Vol. 30, No. 7, pp. 1525 to 1529 (1991) (Non Patent Literature 2) discloses a method for growing a tungsten film.

### SUMMARY

A transistor according to an aspect of the present disclosure includes a semiconductor stack portion, a source electrode, a drain electrode, a gate electrode, a first polysilicon film, a dielectric layer, a first plug, and a first wiring. The source electrode and the drain electrode are provided on the semiconductor stack portion. The gate electrode is provided between the source electrode and the drain electrode on the semiconductor stack portion. The first polysilicon film is provided on a first electrode that is one of the gate electrode, the source electrode, and the drain electrode. The dielectric layer is provided on the semiconductor stack portion and covers the gate electrode, the source electrode, the drain electrode, and the first polysilicon film. The dielectric layer has a first opening formed on the first polysilicon film. The first plug contains tungsten, is embedded in the first opening, and is in contact with the first polysilicon film. The first wiring is provided on the dielectric layer and is in contact with the first plug.

### BRIEF DESCRIPTION OF THE DRAWINGS

FIG. 1 is a cross-sectional view showing the configuration of a transistor according to an embodiment of the present disclosure.

FIGS. 2A, 2B, and 2C are cross-sectional views showing each step in a method for manufacturing a transistor.

FIGS. 3A and 3B are cross-sectional views showing each step in the method for manufacturing a transistor.

FIGS. 4A and 4B are cross-sectional views showing each step in the method for manufacturing a transistor.

FIGS. 5A, 5B, and 5C are cross-sectional views showing each step in a method for manufacturing a transistor according to a reference example.

FIGS. 6A, 6B, and 6C are cross-sectional views showing each step in the method for manufacturing a transistor according to the reference example.

FIGS. 7A and 7B are cross-sectional views showing each step in the method for manufacturing a transistor according to the reference example.

FIG. 8 is a plan view showing a wiring shape as a modification example.

### DETAILED DESCRIPTION

### Problem to be Solved by Present Disclosure

In a transistor, for at least one electrode of a gate electrode, a source electrode, and a drain electrode, a wiring provided on the electrode and a plug connecting the wiring and the electrode to each other may be provided. For example, when a transistor is used in a high frequency band, it is required to reduce the gate resistance. On the other hand, transistors are required to be smaller, and the cross-sectional area of the gate electrode is becoming smaller year by year. The gate resistance increases as the cross-sectional area of the gate electrode decreases. By forming a wiring along the gate electrode in a wiring layer above the gate electrode and connecting the gate electrode to the wiring through a plug penetrating a dielectric layer interposed between the wiring layer and the gate electrode, the gate resistance can be reduced.

However, forming the plug that penetrates the dielectric layer has the following problems. When forming a plug, an opening is formed in the dielectric layer, and a metal material (for example, tungsten) is embedded in the opening using a film forming method such as thermal CVD. As the width of the plug decreases due to miniaturization of the electrode, the width of the opening also decreases. If the aspect ratio (value obtained by dividing the depth by the width) of the opening is large, the metal material does not enter the opening sufficiently, making it difficult to form a plug. Therefore, there is no choice but to make the opening shallow by forming the dielectric layer thin. In this case, it may be necessary to form the plug and the wiring so as to overlap each other in more layers. As a result, the number of steps for forming the plug and the wiring increases.

### Effects of Present Disclosure

According to the present disclosure, it is possible to provide a transistor and a method for manufacturing a transistor that can increase the aspect ratio of an opening in which a plug is embedded.

### Description of Embodiments of Present Disclosure

First, embodiments of the present disclosure will be listed and described. [1] A transistor according to an aspect of the present disclosure includes a semiconductor stack portion, a source electrode, a drain electrode, a gate electrode, a first polysilicon film, a dielectric layer, a first plug, and a first wiring. The source electrode and the drain electrode are provided on the semiconductor stack portion. The gate electrode is provided between the source electrode and the drain electrode on the semiconductor stack portion. The first polysilicon film is provided on a first electrode that is one of the gate electrode, the source electrode, and the drain electrode. The dielectric layer is provided on the semiconductor stack portion and covers the gate electrode, the source electrode, the drain electrode, and the first polysilicon film. The dielectric layer has a first opening formed on the first polysilicon film. The first plug contains tungsten, is embedded in the first opening, and is in contact with the first polysilicon film. The first wiring is provided on the dielectric layer and is in contact with the first plug.

This transistor includes the first polysilicon film on the first electrode that is one of the gate electrode, the source electrode, and the drain electrode. When forming the first plug containing tungsten, polysilicon acts as a catalyst to decompose the material containing tungsten (for example, WF₆). Therefore, the material containing tungsten of the first plug is selectively grown on the first polysilicon film exposed in the opening. For this reason, even if the aspect ratio of the opening is large, the material of the first plug can sufficiently enter the first opening to form the first plug suitably. Therefore, according to the transistor, the aspect ratio of the opening in which the first plug is embedded can be increased. As a result, the number of layers of the plug and the wiring can be reduced to suppress an increase in the number of steps for forming the plug and the wiring.
[2] In the transistor described in [1] above, at least a portion of the first electrode in contact with the first polysilicon film may contain nickel in its composition. When forming the first polysilicon film, nickel in the first electrode acts to promote the decomposition of the material (for example, SiH₄) of the first polysilicon film. Therefore, the first polysilicon film can be easily formed.
[3] In the transistor described in [2] above, at least a portion of the first electrode in contact with the first polysilicon film may be made of only nickel. In this case, the decomposition of the material of the first polysilicon film is promoted more effectively. Therefore, the first polysilicon film can be formed more easily.
[4] In the transistor described in any one of [1] to [3] above, the first plug may be made of only tungsten. In this case, polysilicon can act as a catalyst to more suitably form the first plug in the first opening.
[5] In the transistor described in any one of [1] to [4] above, a ratio (D/A) between a depth D and an opening width A of the first opening may be 2 or more. According to the transistor described in any one of [1] to [4] above, the first plug can be embedded even in the first opening having such a large aspect ratio.
[6] The transistor described in any one of [1] to [5] above may further include a second polysilicon film and a third polysilicon film. The second polysilicon film is provided on a second electrode that is another one of the gate electrode, the source electrode, and the drain electrode. The third polysilicon film is provided on a third electrode that is the remaining one of the gate electrode, the source electrode, and the drain electrode. The dielectric layer may further cover the second polysilicon film and the third polysilicon film. The dielectric layer may further have a second opening and a third opening formed on the second polysilicon film and the third polysilicon film, respectively. The transistor may further include a second plug, a third plug, a second wiring, and a third wiring. The second plug contains tungsten, is embedded in the second opening, and is in contact with the second polysilicon film. The third plug contains tungsten, is embedded in the third opening, and is in contact with the third polysilicon film. The second wiring and the third wiring are provided on the dielectric layer and are in contact with the second plug and the third plug, respectively. In this case, the wiring and the plug can be provided for all of the gate electrode, the source electrode, and the drain electrode. For example, when a transistor is used in a high frequency band, it is required to reduce noise superimposed on the gate signal. Generally, the source electrode is connected to the reference potential line (GND line). Therefore, by interposing the wiring corresponding to the gate electrode among the first wiring, the second wiring, and the third wiring using the wiring corresponding to the source electrode among the first wiring, the second wiring, and the third wiring, it is possible to reduce noise superimposed on the gate signal.
[7] In the transistor described in [6] above, at least a portion of the second electrode in contact with the second polysilicon film and at least a portion of the third electrode in contact with the third polysilicon film may contain nickel in their composition. When forming the second polysilicon film and the third polysilicon film, nickel in the second electrode and the third electrode acts to promote the decomposition of the material (for example, SiH₄) of the second polysilicon film and the third polysilicon film. Therefore, the second polysilicon film and the third polysilicon film can be easily formed.
[8] In the transistor described in [6] or [7] above, the gate electrode, the source electrode, and the drain electrode may contain nickel in their composition. The semiconductor stack portion may have a semiconductor layer containing a group III nitride semiconductor and in contact with the gate electrode, a first high concentration n-type semiconductor region containing a group III nitride semiconductor and in contact with the source electrode, and a second high concentration n-type semiconductor region containing a group III nitride semiconductor and in contact with the drain electrode. An electrode containing nickel in its composition makes a Schottky contact with, for example, a group III nitride semiconductor, such as GaN or AlGaN, which has a low dopant concentration or is undoped. However, the electrode containing nickel in its composition has a sufficiently low contact resistance with respect to a high concentration n-type group III nitride semiconductor such as high concentration n-type GaN. Therefore, according to the transistor described in [8] above, even if the gate electrode, the source electrode, and the drain electrode contain nickel in their composition, it is possible to obtain a suitable contact between these electrodes and the semiconductor stack portion. In addition, nickel in each of the gate electrode, the source electrode, and the drain electrode acts to promote the decomposition of the material (for example, SiH₄) of the first polysilicon film, the second polysilicon film, and the third polysilicon film.
[9] In the transistor described in [8] above, the semiconductor stack portion may include: a channel layer provided between the first high concentration n-type semiconductor region and the second high concentration n-type semiconductor region; and an electron supply layer having a larger bandgap than the channel layer. In this case, a high electron mobility transistor (HEMT) can be obtained.
[10] A method for manufacturing a transistor according to an aspect of the present disclosure includes forming a source electrode, a drain electrode, and a gate electrode, forming a first polysilicon film, forming a dielectric layer, forming a first opening, forming a first plug, and forming a first wiring. In the forming the source electrode, the drain electrode, and the gate electrode, the source electrode, the drain electrode, and the gate electrode located between the source electrode and the drain electrode are formed on a semiconductor stack portion. In the forming the first polysilicon film, a first polysilicon film is formed on a first electrode that is one of the gate electrode, the source electrode, and the drain electrode. In the forming the dielectric layer, a dielectric layer covering the gate electrode, the source electrode, the drain electrode, and the first polysilicon film is formed on the semiconductor stack portion. In the forming the first opening, a first opening is formed on the first polysilicon film in the dielectric layer. In the forming the first plug, a first plug in contact with the first polysilicon film is formed by embedding a material containing tungsten in the first opening. In the forming the first wiring, a first wiring in contact with the first plug is formed on the dielectric layer.

In this manufacturing method, in the forming the source electrode, the drain electrode, and the gate electrode, the first polysilicon film is formed on the first electrode that is one of the gate electrode, the source electrode, and the drain electrode. When forming the first plug containing tungsten in the forming the first plug, polysilicon acts as a catalyst to decompose the material containing tungsten (for example, WF₆). Therefore, the material of the first plug containing tungsten is selectively grown on the first polysilicon film exposed in the first opening. For this reason, even if the aspect ratio of the first opening is large, the material of the first plug can sufficiently enter the first opening to form the first plug suitably. Therefore, according to the transistor, the aspect ratio of the first opening in which the first plug is embedded can be increased. As a result, the number of stages of the first plug and the first wiring can be reduced to suppress an increase in the number of steps for forming the first plug and the first wiring.
[11] In the manufacturing method described in [10] above, in the forming the source electrode, the drain electrode, and the gate electrode, the first electrode may be formed so that at least a portion of the first electrode in contact with the first polysilicon film contains nickel in its composition. When forming the first polysilicon film, nickel in the first electrode acts to promote the decomposition of the material (for example, SiH₄) of the first polysilicon film. Therefore, the first polysilicon film can be easily formed.
[12] In the manufacturing method described in [11] above, in the forming the source electrode, the drain electrode, and the gate electrode, the first electrode may be formed so that at least a portion of the first electrode in contact with the first polysilicon film is made of only nickel. In this case, the decomposition of the material of the first polysilicon film is promoted more effectively. Therefore, the first polysilicon film can be formed more easily.
[13] In the manufacturing method described in [11] or [12] above, in the forming the first polysilicon film, the first polysilicon film may be formed at room temperature by using SiH₄ as a raw material for film formation. When SiH₄ is used as a raw material for film formation, nickel in the first electrode acts more effectively to further promote the decomposition of the material (SiH₄) of the first polysilicon film. Therefore, the first polysilicon film can be easily formed at room temperature.
[14] In the manufacturing method described in any one of [10] to [13] above, in the forming the first plug, the first plug made of only tungsten may be formed. In this case, polysilicon can act as a catalyst to more suitably form the first plug in the first opening.
[15] In the manufacturing method described in any one of [10] to [14] above, in the forming the first opening, a ratio (D/A) between a depth D and an opening width A of the first opening may be set to 2 or more. According to the manufacturing method described in any one of to above, the first plug can be embedded even in the first opening having such a large aspect ratio.
[16] In the manufacturing method described in any one of [10] to [15] above, in the forming the first polysilicon film, a second polysilicon film may be further formed on a second electrode that is another one of the gate electrode, the source electrode, and the drain electrode, and a third polysilicon film may be further formed on a third electrode that is the remaining one of the gate electrode, the source electrode, and the drain electrode. In the forming the dielectric layer, the dielectric layer further covering the second polysilicon film and the third polysilicon film may be formed. In the forming the first opening, a second opening may be further formed on the second polysilicon film in the dielectric layer, and a third opening may be further formed on the third polysilicon film in the dielectric layer. In the forming the first plug, a second plug in contact with the second polysilicon film and a third plug in contact with the third polysilicon film may be further formed by further embedding a material containing tungsten in the second opening and the third opening. In the forming the first wiring, a second wiring in contact with the second plug and a third wiring in contact with the third plug may be further formed on the dielectric layer. In this case, the wiring and the plug can be provided for all of the gate electrode, the source electrode, and the drain electrode. For example, by interposing the wiring corresponding to the gate electrode among the first wiring, the second wiring, and the third wiring using the wiring corresponding to the source electrode among the first wiring, the second wiring, and the third wiring, it is possible to reduce noise superimposed on the gate signal.
[17] In the manufacturing method described in [16] above, in the forming the source electrode, the drain electrode, and the gate electrode, the second electrode and the third electrode may be formed. The second electrode contains nickel in the composition of at least a portion in contact with the second polysilicon film. The third electrode contains nickel in the composition of at least a portion in contact with the third polysilicon film. When forming the second polysilicon film and the third polysilicon film, nickel in the second electrode and the third electrode acts to promote decomposition of the material (for example, SiH₄) of the second polysilicon film and the third polysilicon film. Therefore, the second polysilicon film and the third polysilicon film can be easily formed.
[18] In the manufacturing method described in [16] or [17] above, the semiconductor stack portion may have a semiconductor layer containing a group III nitride semiconductor, a first high concentration n-type semiconductor region containing a group III nitride semiconductor, and a second high concentration n-type semiconductor region containing a group III nitride semiconductor. In the forming the source electrode, the drain electrode, and the gate electrode, the gate electrode, the source electrode, and the drain electrode each containing nickel in their composition may be formed. In the forming the source electrode, the drain electrode, and the gate electrode, the gate electrode may be brought into Schottky contact with the semiconductor layer, the source electrode may be brought into contact with the first high concentration n-type semiconductor region, and the drain electrode may be brought into contact with the second high concentration n-type semiconductor region. An electrode containing nickel in its composition makes a Schottky contact with, for example, a group III nitride semiconductor, such as GaN or AlGaN, which has a low dopant concentration or is undoped. However, the electrode containing nickel in its composition has a sufficiently low contact resistance with respect to a high concentration n-type group III nitride semiconductor such as high concentration n-type GaN. Therefore, according to the transistor described in [18] above, even if the gate electrode, the source electrode, and the drain electrode contain nickel in their composition, it is possible to obtain a suitable contact form between these electrodes and the semiconductor stack portion. In addition, nickel in each of the gate electrode, the source electrode, and the drain electrode acts to promote the decomposition of the material (for example, SiH₄) of the first polysilicon film, the second polysilicon film, and the third polysilicon film.
[19] In the manufacturing method described in [18] above, the semiconductor stack portion may include: a channel layer provided between the first high concentration n-type semiconductor region and the second high concentration n-type semiconductor region; and an electron supply layer having a larger bandgap than the channel layer. In this case, a high electron mobility transistor (HEMT) can be obtained.

### Details of Embodiment of Present Disclosure

Specific examples of a transistor and a method for manufacturing a transistor according to the present embodiment will be described with reference to the diagrams as necessary. In addition, the present invention is not limited to the examples, and is indicated by the appended claims and is intended to include all modifications within the meaning and scope equivalent to the appended claims. In the following description, the same elements will be denoted by the same reference numerals in the description of the diagrams, and repeated description thereof will be omitted.

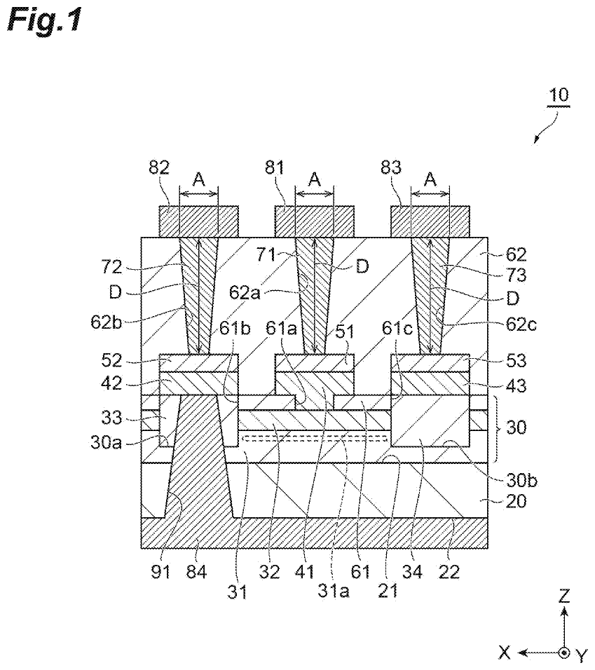

FIG. 1 is a cross-sectional view showing the configuration of a transistor 10 according to an embodiment of the present disclosure. In FIG. 1, an XYZ orthogonal coordinate system is also shown for convenience of explanation. The transistor 10 according to the present embodiment is a high electron mobility transistor (HEMT) mainly containing group III nitride semiconductors such as GaN and AlGaN. The transistor 10 is used in power amplifiers (for example, power amplifiers for mobile base stations) because of its characteristics such as low noise, high gain at high frequencies, and high withstand voltage. The transistor 10 is used in high frequency bands, for example, from 10 GHz to 80 GHz. The transistor 10 includes a substrate 20, a semiconductor stack portion 30, a gate electrode 41, a source electrode 42, a drain electrode 43, polysilicon films 51, 52, and 53, dielectric layers 61 and 62, plugs 71, 72, and 73, and wirings 81, 82, 83, and 84.

The substrate 20 is a plate-shaped member having a main surface 21 and a back surface 22. The substrate 20 is a substrate for crystal growth. The substrate 20 may be a semiconductor substrate. The substrate 20 is, for example, a SiC substrate or a GaN substrate. The substrate 20 may also be made of other materials excluding semiconductors, for example, sapphire. The thickness direction of the substrate 20 is along the Z direction, and the main surface 21 and the back surface 22 extend along the X direction and the Y direction.

The semiconductor stack portion 30 includes a channel layer 31, an electron supply layer (barrier layer) 32, a first high concentration n-type semiconductor region 33, and a second high concentration n-type semiconductor region 34. The channel layer 31 is a semiconductor layer epitaxially grown on the main surface 21 of the substrate 20. The channel layer 31 mainly contains a group III nitride semiconductor such as gallium nitride (GaN). As an example, the channel layer 31 is made of only a group III nitride semiconductor. The thickness of the channel layer 31 is, for example, 1000 nm or more and 3000 nm or less.

The electron supply layer 32 is a semiconductor layer epitaxially grown on the channel layer 31, and has a larger bandgap than the channel layer 31. The stacking direction of the channel layer 31 and the electron supply layer (barrier layer) 32 is along the Z direction. The electron supply layer 32 mainly contains a group III nitride semiconductor. As an example, the electron supply layer 32 is made of only a group III nitride semiconductor excluding n-type impurities. Examples of such group III nitride semiconductors include AlGaN and InAlN. The thickness of the electron supply layer 32 is, for example, 10 nm or more and 30 nm or less. Two-dimensional electron gas (2DEG) is generated at the interface between the channel layer 31 and the electron supply layer 32 due to the piezo effect. As a result, a channel region 31a is formed near the surface of the channel layer 31 on the electron supply layer 32 side. The electron supply layer 32 is of low concentration n-type or is undoped. The n-type impurity concentration in the electron supply layer 32 is, for example, 0 cm⁻³ or more and 10¹⁶ cm⁻³ or less.

The first high concentration n-type semiconductor region 33 and the second high concentration n-type semiconductor region 34 are regions epitaxially grown within recesses 30a and 30b, respectively, which are formed by etching the electron supply layer 32 or etching a part of the channel layer 31 in addition to the electron supply layer 32. The first high concentration n-type semiconductor region 33 and the second high concentration n-type semiconductor region 34 mainly contain a high concentration n-type group III nitride semiconductor. As an example, the first high concentration n-type semiconductor region 33 and the second high concentration n-type semiconductor region 34 are made of only a high concentration n-type group III nitride semiconductor. The first high concentration n-type semiconductor region 33 and the second high concentration n-type semiconductor region 34 are made of, for example, only high concentration n-type GaN. The n-type impurity is, for example, silicon (Si). The n-type impurity concentration in the first high concentration n-type semiconductor region 33 and the second high concentration n-type semiconductor region 34 is, for example, 10¹⁹ cm⁻³ or more and 10²¹ cm⁻³ or less.

The second high concentration n-type semiconductor region 34 is aligned with the first high concentration n-type semiconductor region 33 in a direction (for example, the X direction) crossing the stacking direction of the channel layer 31 and the electron supply layer 32. Then, a part of the channel layer 31 and the electron supply layer 32 are provided between the first high concentration n-type semiconductor region 33 and the second high concentration n-type semiconductor region 34. The thickness of each of the first high concentration n-type semiconductor region 33 and the second high concentration n-type semiconductor region 34 is equal to or greater than the thickness of the electron supply layer 32, and is smaller than the combined thickness of the electron supply layer 32 and the channel layer 31. Therefore, the side surfaces of the first high concentration n-type semiconductor region 33 and the second high concentration n-type semiconductor region 34 are in contact with the channel region 31a. The thickness of each of the first high concentration n-type semiconductor region 33 and the second high concentration n-type semiconductor region 34 is, for example, 20 nm or more and 100 nm or less.

The dielectric layer 61 is provided on the semiconductor stack portion 30 and covers the surface of the semiconductor stack portion 30. The dielectric layer 61 mainly contains an inorganic dielectric. The dielectric layer 61 mainly contains a silicon compound such as silicon nitride (SiN), silicon oxide (SiO₂), or silicon oxynitride (SiON). In a practical example, the dielectric layer 61 is made of only SiN, SiO₂, or SiON. The dielectric layer 61 has a gate opening 61a for the gate electrode 41, a source opening 61b for the source electrode 42, and a drain opening 61c for the drain electrode 43. The gate opening 61a is provided on the electron supply layer 32. The first high concentration n-type semiconductor region 33 is embedded in the source opening 61b. The second high concentration n-type semiconductor region 34 is embedded in the drain opening 61c.

The gate electrode 41, the source electrode 42, and the drain electrode 43 are provided on the semiconductor stack portion 30. The gate electrode 41 is located between the source electrode 42 and the drain electrode 43 in the X direction. The gate electrode 41, the source electrode 42, and the drain electrode 43 extend along a direction (for example, the Y direction) crossing the alignment direction (for example, the X direction) of these electrodes. The gate electrode 41 is embedded in the gate opening 61a and has a T-shaped cross section. The gate electrode 41 is in contact with the electron supply layer 32 through the gate opening 61a. The gate electrode 41 makes Schottky contact with the electron supply layer 32.

At least a portion of the gate electrode 41 in contact with the electron supply layer 32 includes a material that makes Schottky contact with the electron supply layer 32. A material that makes Schottky contact with group III nitride semiconductors in the electron supply layer 32 is, for example, nickel (Ni). In addition, a portion of the gate electrode 41 forming a surface on a side opposite to the electron supply layer 32, in other words, at least a portion of the gate electrode 41 in contact with the polysilicon film 51 contains Ni. In a practical example, at least the portion of the gate electrode 41 in contact with the polysilicon film 51 is made of only Ni. Alternatively, in another practical example, the entire gate electrode 41 contains Ni in its composition or is made of only Ni.

The source electrode 42 is provided on the first high concentration n-type semiconductor region 33 exposed from the source opening 61b, and is in contact with the first high concentration n-type semiconductor region 33. At least a portion of the source electrode 42 in contact with the first high concentration n-type semiconductor region 33 contains a material having a low contact resistance with respect to the first high concentration n-type semiconductor region 33. The material having a low contact resistance with respect to a high concentration n-type group III nitride semiconductor in the first high concentration n-type semiconductor region 33 is, for example, Ni. In addition, a portion of the source electrode 42 forming a surface on a side opposite to the first high concentration n-type semiconductor region 33, in other words, at least a portion of the source electrode 42 in contact with the polysilicon film 52 contains Ni. In a practical example, at least a portion of the source electrode 42 in contact with the polysilicon film 52 is made of only Ni. Alternatively, in another practical example, the entire source electrode 42 contains Ni in its composition or is made of only Ni. In addition, the source electrode 42 may be provided on a recess formed by etching a part of the first high concentration n-type semiconductor region 33.

The drain electrode 43 is provided on the second high concentration n-type semiconductor region 34 exposed from the drain opening 61c, and is in contact with the second high concentration n-type semiconductor region 34. At least a portion of the drain electrode 43 in contact with the second high concentration n-type semiconductor region 34 contains a material having a low contact resistance with respect to the second high concentration n-type semiconductor region 34. The material having a low contact resistance with respect to a high concentration n-type group III nitride semiconductor in the second high concentration n-type semiconductor region 34 is, for example, Ni. In addition, a portion of the drain electrode 43 forming a surface on a side opposite to the second high concentration n-type semiconductor region 34, in other words, at least a portion of the drain electrode 43 in contact with the polysilicon film 53 contains Ni. In a practical example, at least the portion of the drain electrode 43 in contact with the polysilicon film 53 is made of only Ni. Alternatively, in another practical example, the entire drain electrode 43 contains Ni in its composition or is made of only Ni. In addition, the drain electrode 43 may be provided on a recess formed by etching a part of the second high concentration n-type semiconductor region 34.

In the present embodiment, one of the gate electrode 41, the source electrode 42, and the drain electrode 43 corresponds to a first electrode in the present disclosure. The remaining two of the gate electrode 41, the source electrode 42, and the drain electrode 43 correspond to a second electrode and a third electrode in the present disclosure.

The polysilicon film 51 is provided on the gate electrode 41. The polysilicon film 52 is provided on the source electrode 42. The polysilicon film 53 is provided on the drain electrode 43. Thus, the polysilicon films 51, 52, and 53 are selectively formed on the gate electrode 41, the source electrode 42, and the drain electrode 43, respectively. In addition, the polysilicon films 51, 52, and 53 completely overlap the gate electrode 41, the source electrode 42, and the drain electrode 43, respectively, without protruding or lacking therefrom in plan view. The polysilicon films 51, 52, and 53 extend in the Y direction along the gate electrode 41, the source electrode 42, and the drain electrode 43, respectively.

The polysilicon films 51, 52, and 53 are electrically separated from each other. The polysilicon films 51, 52, and 53 are made of only polysilicon (polycrystalline silicon). In an example, the polysilicon films 51, 52, and 53 are in contact with the gate electrode 41, the source electrode 42, and the drain electrode 43, respectively. The thickness of each of the polysilicon films 51, 52, and 53 is, for example, 5 nm or more and 10 nm or less.

In the present embodiment, the polysilicon film provided on the first electrode among the polysilicon films 51, 52, and 53 corresponds to a first polysilicon film in the present disclosure. The polysilicon film provided on the second electrode among the polysilicon films 51, 52, and 53 corresponds to a second polysilicon film in the present disclosure. The polysilicon film provided on the third electrode among the polysilicon films 51, 52, and 53 corresponds to a third polysilicon film in the present disclosure.

The dielectric layer 62 is provided on the semiconductor stack portion 30 and on the dielectric layer 61. The dielectric layer 62 covers the gate electrode 41, the source electrode 42, the drain electrode 43, and the polysilicon films 51, 52, and 53. The dielectric layer 62 mainly contains an inorganic dielectric. The dielectric layer 62 mainly contains a silicon compound such as silicon nitride (SiN), silicon oxide (SiO₂), or silicon oxynitride (SiON). In a practical example, the dielectric layer 62 is made of only SiN, SiO₂, or SiON. The dielectric layer 62 may be made of the same material as the dielectric layer 61.

The dielectric layer 62 includes an opening (contact hole) 62a formed on the polysilicon film 51, an opening (contact hole) 62b formed on the polysilicon film 52, and an opening (contact hole) 62c formed on the polysilicon film 53. In plan view, the openings 62a, 62b, and 62c extend in the Y direction along the gate electrode 41, the source electrode 42, and the drain electrode 43, respectively. In addition, the openings 62a, 62b, and 62c penetrate the dielectric layer 62 in the thickness direction (Z direction) of the dielectric layer 62. In other words, one end of each of the openings 62a, 62b, and 62c in the thickness direction (Z direction) of dielectric layer 62 reaches each of the polysilicon films 51, 52, and 53. The other ends of the openings 62a, 62b, and 62c in the thickness direction (Z direction) of the dielectric layer 62 reach the surface of the dielectric layer 62 on a side opposite to the dielectric layer 61. The widths of the openings 62a, 62b, and 62c in the X direction gradually decrease from the surface of the dielectric layer 62 toward the polysilicon films 51, 52, and 53.

The depth D of each of the openings 62a, 62b, and 62c is, for example, 1000 nm or more and 4000 nm or less. In addition, the opening width A of each of the openings 62a, 62b, and 62c is, for example, 500 nm or more and 2000 nm or less. The opening width A referred to herein means a value obtained by averaging, over the Y direction, the width of each of the openings 62a, 62b, and 62c in the X direction at one end on a side opposite to the polysilicon films 51, 52, and 53 (that is, one end located on the surface of the dielectric layer 62) of both ends of each of the openings 62a, 62b, and 62c in the thickness direction (Z direction) of the dielectric layer 62. In addition, the aspect ratio (D/A) of each of the openings 62a, 62b, and 62c is, for example, 2 or more and 8 or less.

In the present embodiment, the opening formed on the first polysilicon film among the openings 62a, 62b, and 62c corresponds to a first opening in the present disclosure. The opening formed on the second polysilicon film among the openings 62a, 62b, and 62c corresponds to a second opening in the present disclosure. The opening formed on the third polysilicon film among the openings 62a, 62b, and 62c corresponds to a third polysilicon film in the present disclosure.

The plugs 71, 72, and 73 are embedded in the openings 62a, 62b, and 62c, respectively, and are in contact with the polysilicon films 51, 52, and 53, respectively. In plan view, the plugs 71, 72, and 73 extend in the Y direction along the gate electrode 41, the source electrode 42, and the drain electrode 43, respectively. The plugs 71, 72, and 73 are made of metal and contain tungsten (W). For example, the plugs 71, 72, and 73 are made of only W. In the thickness direction (Z direction) of the dielectric layer 62, one end of each of the plugs 71, 72, and 73 is in contact with each of the polysilicon films 51, 52, and 53, and the other ends of the plugs 71, 72, and 73 are exposed from the dielectric layer 62.

In the present embodiment, the plug embedded in the first opening among the plugs 71, 72, and 73 corresponds to a first plug in the present disclosure. The plug embedded in the second opening among the plugs 71, 72, and 73 corresponds to a second plug in the present disclosure. The plug embedded in the third opening among the plugs 71, 72, and 73 corresponds to a third plug in the present disclosure.

The wirings 81, 82, and 83 are metal films and are provided on the dielectric layer 62. The wirings 81, 82, and 83 are in contact with the other ends of the plugs 71, 72, and 73, respectively. Therefore, the wirings 81, 82, and 83 are electrically connected to the gate electrode 41, the source electrode 42, and the drain electrode 43, respectively. The wirings 81, 82, and 83 contain, for example, aluminum (Al). As an example, the wirings 81, 82, and 83 are made of only Al. In plan view, the wirings 81, 82, and 83 extend in the Y direction along the gate electrode 41, the source electrode 42, and the drain electrode 43, respectively. The thickness of each of the wirings 81, 82, and 83 is, for example, 1000 nm or more and 5000 nm or less.

The wiring 84 is a metal film and is provided on the back surface 22 of the substrate 20. In addition, the wiring 84 is embedded in an opening 91 that reaches the source electrode 42 from the back surface 22 of the substrate 20, and is electrically connected to the source electrode 42 by coming into contact with the source electrode 42. The wiring 84 is made of metal such as gold (Au).

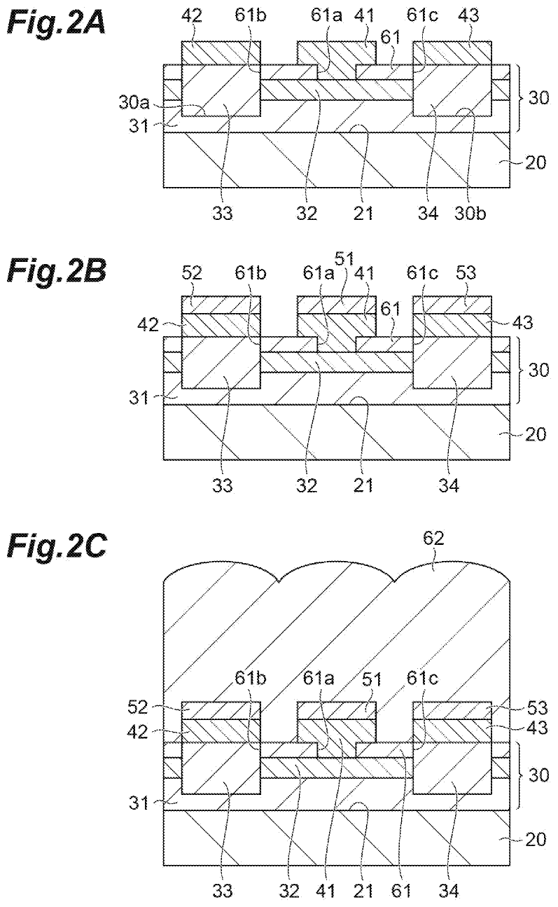

A method for manufacturing the transistor 10 according to the present embodiment having the above configuration will be described. FIGS. 2A to 2C, 3A, 3B, 4A and 4B are cross-sectional views showing each step in the method for manufacturing the transistor 10.

First, as shown in FIG. 2A, the channel layer 31 and the electron supply layer 32 are sequentially epitaxially grown on the main surface 21 of the substrate 20. Then, the dielectric layer 61 is formed on the electron supply layer 32 by using, for example, a chemical vapor deposition (CVD) method. A first resist pattern having openings corresponding to the source electrode 42 and the drain electrode 43 is formed on the dielectric layer 61 using a photolithography method. By using the first resist pattern as a mask, the source opening 61b and the drain opening 61c of the dielectric layer 61 are formed by reactive ion etching. In addition, by continuing the reactive ion etching, the recesses 30a and 30b penetrating the electron supply layer 32 and reaching the channel layer 31 are formed. By selectively re-growing the semiconductor material of the first high concentration n-type semiconductor region 33 and the second high concentration n-type semiconductor region 34 in the recesses 30a and 30b, the first high concentration n-type semiconductor region 33 and the second high concentration n-type semiconductor region 34 are formed. As a result, the semiconductor stack portion 30 having the channel layer 31, the electron supply layer 32, the first high concentration n-type semiconductor region 33, and the second high concentration n-type semiconductor region 34 is formed. Thereafter, the first resist pattern is removed using an organic solvent. Through the above steps, the semiconductor stack portion 30 is formed. By using the lift-off method, the source electrode 42 is formed on the first high concentration n-type semiconductor region 33, and the drain electrode 43 is formed on the second high concentration n-type semiconductor region 34. A second resist pattern having an opening corresponding to the gate electrode 41 is formed on the dielectric layer 61 using a photolithography method. By using the second resist pattern as a mask, the gate opening 61a in the dielectric layer 61 is formed by reactive ion etching. Thereafter, the second resist pattern is removed using an organic solvent. By using the lift-off method, the gate electrode 41 is formed on the electron supply layer 32 in the gate opening 61a and on the dielectric layer 61 around the electron supply layer 32 using, for example, a vacuum evaporation method.

Then, as shown in FIG. 2B, the polysilicon films 51, 52, and 53 are formed by selectively depositing polysilicon on the gate electrode 41, the source electrode 42, and the drain electrode 43. In this step, a polysilicon material, for example, monosilane (SiH₄) is introduced into a chamber for plasma CVD. At this time, on the surface of the metal containing Ni (or made of only Ni), the polysilicon material (for example, SiH₄) decomposes at room temperature (see Non Patent Literature 1). As described above, at least a portion of the gate electrode 41 in contact with the polysilicon film 51, at least a portion of the source electrode 42 in contact with the polysilicon film 52, and at least a portion of the drain electrode 43 in contact with the polysilicon film 53 contain Ni. Therefore, polysilicon is selectively deposited on the gate electrode 41, the source electrode 42, and the drain electrode 43 at room temperature.

Then, as shown in FIG. 2C, the dielectric layer 62 that covers the gate electrode 41, the source electrode 42, the drain electrode 43, and the polysilicon films 51, 52, and 53 is formed on the semiconductor stack portion 30. In this step, the dielectric layer 62 is formed using, for example, a plasma CVD method. The uneven shape on the semiconductor stack portion 30 caused by the gate electrode 41, the source electrode 42, the drain electrode 43, and the polysilicon films 51, 52, and 53 is transferred to the surface of the dielectric layer 62. Thereafter, the surface of the dielectric layer 62 is planarized using a chemical mechanical polishing (CMP) method.

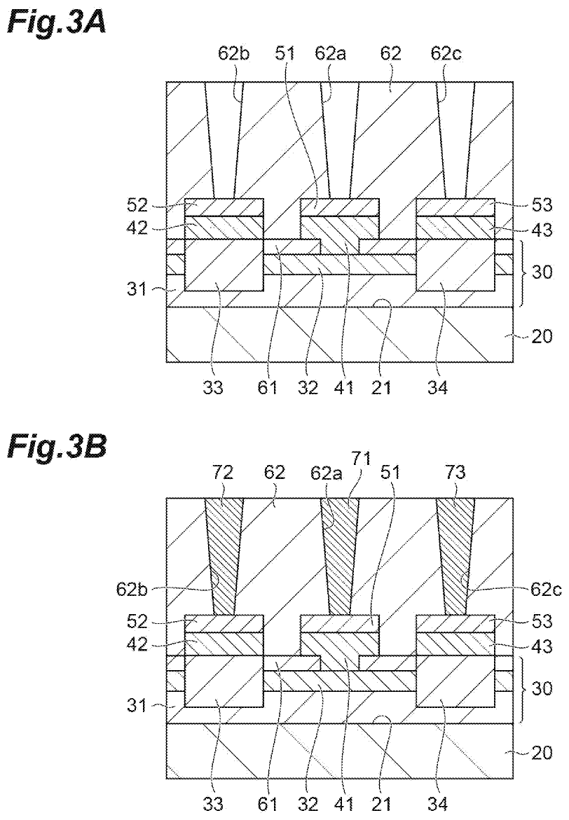

Then, as shown in FIG. 3A, in the dielectric layer 62, the opening 62a reaching the polysilicon film 51 is formed on the polysilicon film 51, the opening 62b reaching the polysilicon film 52 is formed on the polysilicon film 52, and the opening 62c reaching the polysilicon film 53 is formed on the polysilicon film 53. In this step, the openings 62a, 62b, and 62c are formed by anisotropic etching such as dry etching. When the dielectric layer 62 contains a silicon compound, the etching gas is, for example, a fluorine-based gas. As described above, the aspect ratio (D/A) of each of the openings 62a, 62b, and 62c is, for example, 2 or more and 8 or less.

Then, as shown in FIG. 3B, by embedding a material containing W in the openings 62a, 62b, and 62c, the plug 71 in contact with the polysilicon film 51, the plug 72 in contact with the polysilicon film 52, and the plug 73 in contact with the polysilicon film 53 are formed. At this time, the polysilicon contained in the polysilicon films 51, 52, and 53 acts as a catalyst to decompose the material containing W (for example, WF₆) as shown in reaction formula (1) below (see Non Patent Literature 2).

WF₆+3Si→W+3SiF₂ (1)

Therefore, the material of the plugs 71, 72, and 73 containing W is selectively grown on the polysilicon films 51, 52, and 53 exposed in the openings 62a, 62b, and 62c, respectively. For this reason, the material of the plugs 71, 72, and 73 hardly grows on the dielectric layer 62 excluding the openings 62a, 62b, and 62c.

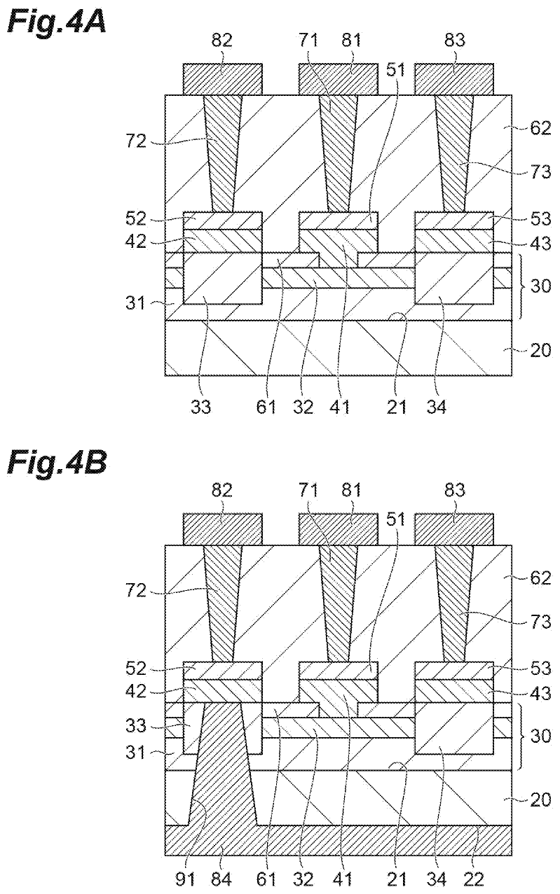

Then, as shown in FIG. 4A, the wirings 81, 82, and 83 in contact with the plugs 71, 72, and 73, respectively, are formed on the dielectric layer 62. In this step, a metal material (for example, Al) for the wirings 81, 82, and 83 is uniformly formed on the dielectric layer 62 using, for example, a sputtering method, and then a resist mask is formed on the metal film using photolithography technology and unnecessary portions of the metal film are removed by dry etching. The etching gas is, for example, a chlorine gas.

Then, as shown in FIG. 4B, the back surface 22 of the substrate 20 is polished to reduce the thickness of the substrate 20, and then the opening 91 extending from the back surface 22 of the substrate 20 to the source electrode 42 is formed in the substrate 20 and the semiconductor stack portion 30. In this step, the opening 91 is formed by anisotropic etching such as dry etching. Then, the wiring 84 is formed on the entire back surface 22, and the metal material of the wiring 84 is embedded in the opening 91. Through the above steps, the transistor 10 according to the present embodiment is manufactured.

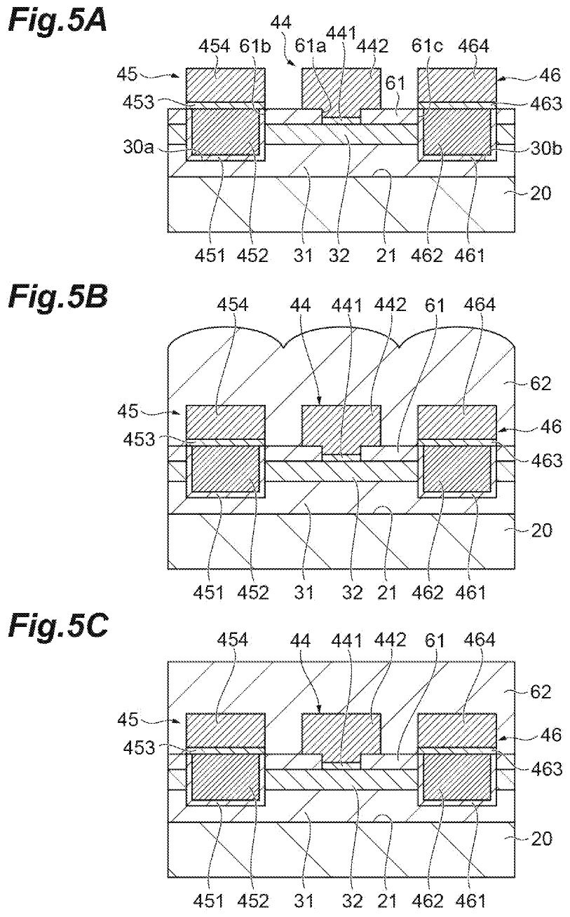

Effects obtained by the transistor 10 according to the present embodiment having the above configuration and the method for manufacturing the same will be described based on comparison with a reference example. FIGS. 5A to 5C, 6A to 6C, 7A and 7B are cross-sectional views showing each step in a method for manufacturing a transistor according to a reference example.

First, as shown in FIG. 5A, the channel layer 31 and the electron supply layer 32 are sequentially grown on the main surface 21 of the substrate 20. Then, the dielectric layer 61 is formed on the electron supply layer 32. After forming the source opening 61b and the drain opening 61c of the dielectric layer 61, the recesses 30a and 30b are formed. The above steps are the same as those in the method for manufacturing the transistor 10.

Thereafter, the source electrode 45 and the drain electrode 46 are formed by using a vacuum evaporation method and a lift-off method in which the same resist mask used to form the recesses 30a and 30b is used. Specifically, titanium (Ti) layers 451 and 461 for ohmic contact are formed in the recesses 30a and 30b, respectively. Then, aluminum (Al) layers 452 and 462 are formed on the Ti layers 451 and 461, respectively. Then, molybdenum (Mo) layers 453 and 463 are formed on the Al layers 452 and 462, respectively. Gold (Au) layers 454 and 464 are formed on the Mo layers 453 and 463, respectively. The Ti layer 451, the Al layer 452, the Mo layer 453, and the Au layer 454 form the source electrode 45. The Ti layer 461, the Al layer 462, the Mo layer 463, and the Au layer 464 form the drain electrode 46.

Then, the gate opening 61a is formed in the dielectric layer 61. A Ni layer 441, which becomes a part of the gate electrode 44, is formed on the electron supply layer 32 in the gate opening 61a by vacuum evaporation method. The Ni layer 441 makes Schottky contact with the electron supply layer 32. Then, an Au layer 442, which becomes the remainder of the gate electrode 44, is formed on the Ni layer 441 by vacuum evaporation method. The Au layer 442 reduces the resistance between the Ni layer 441 and the plug 71. Unnecessary Ni and Au around the gate electrode 44 are removed by lift-off method.

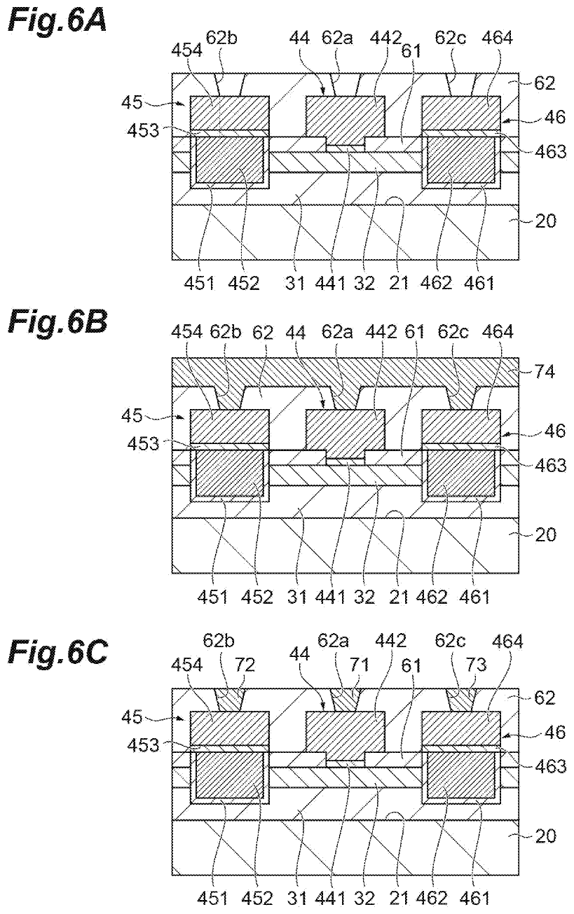

Then, as shown in FIG. 5B, the dielectric layer 62 covering the gate electrode 44, the source electrode 45, and the drain electrode 46 is formed on the dielectric layer 61. Then, as shown in FIG. 5C, the surface of the dielectric layer 62 is planarized using the CMP method. As shown in FIG. 6A, in the dielectric layer 62, the openings 62a, 62b, and 62c reaching the Au layers 442, 454, and 464 are formed on the Au layers 442, 454, and 464, respectively. In the reference example, the aspect ratio (D/A) of each of the openings 62a, 62b, and 62c is about 1. As shown in FIG. 6B, a W film 74 is uniformly formed on the dielectric layer 62 by thermal CVD using WF₆ gas as a source gas. At this time, W is generated by the following reaction formula (2) between the source gas WF₆ and the reducing gas H₂.

WF₆+3H₂→W+6HF (2)

The W film 74 is also embedded in the openings 62a, 62b, and 62c and is in contact with the Au layers 442, 454, and 464. Thereafter, in order to remove a portion of the W film 74 deposited in a region on the dielectric layer 62 excluding the openings 62a, 62b, and 62c, as shown in FIG. 6C, the W film 74 is etched back by isotropic etching using, for example, a fluorine-based gas. As a result, the plug 71 in contact with the Au layer 442, the plug 72 in contact with the Au layer 454, and the plug 73 in contact with the Au layer 464 remain.

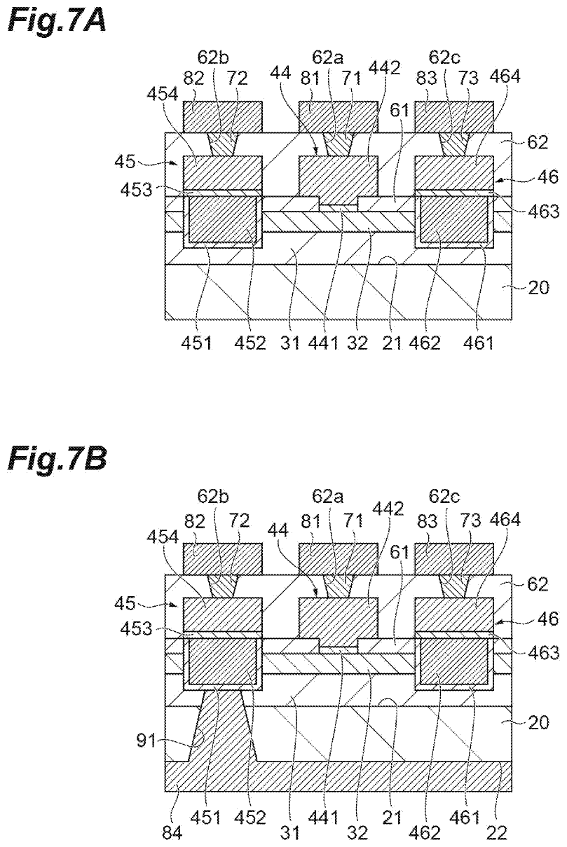

Thereafter, as shown in FIG. 7A, the wirings 81, 82, and 83 in contact with the plugs 71, 72, and 73, respectively, are formed on the dielectric layer 62. As shown in FIG. 7B, the back surface 22 of the substrate 20 is polished to reduce the thickness of the substrate 20, and then the opening 91 extending from the back surface 22 of the substrate 20 to the source electrode 45 is formed. Then, the wiring 84 is formed on the entire back surface 22, and the metal material of the wiring 84 is embedded in the opening 91.

The method for manufacturing a transistor according to the reference example has the following problems. As the widths of the plugs 71, 72, and 73 decrease due to the miniaturization of the gate electrode 44, the source electrode 45, and the drain electrode 46 (particularly, the gate electrode 44), the widths of the openings 62a, 62b, and 62c also decrease. If the aspect ratio of each of the openings 62a, 62b, and 62c is large, the WF₆ gas does not enter the openings 62a, 62b, and 62c sufficiently when forming the W film 74, and voids are generated between the plugs 71, 72, and 73 and the Au layers 442, 454, and 464. Therefore, there is no choice but to make the openings 62a, 62b, and 62c shallow (that is, to reduce the aspect ratio) by forming the dielectric layer 62 thin. In this case, it may be necessary to form the plugs 71, 72, and 73 and the wirings 81, 82, and 83 so as to overlap each other in more layers. As a result, the number of steps for forming the plugs 71, 72, and 73 and the wirings 81, 82, and 83 increases.

In addition, when the W film 74 is formed on the dielectric layer 62 by thermal CVD using WF₆ gas as a source gas, HF vapor is produced as a by-product. Since the HF vapor erodes the silicon compound of the dielectric layer 62, the flatness of the surface of the dielectric layer 62 is adversely affected. In addition, the fluorine-based gas used when etching back the W film 74 also erodes the silicon compound of the dielectric layer 62. For this reason, it is necessary to stop the etchback when the dielectric layer 62 is exposed. This makes it difficult to control the etching time.

To solve the above problem, in the manufacturing method according to the present embodiment, the polysilicon films 51, 52, and 53 are formed on the gate electrode 41, the source electrode 42, and the drain electrode 43, respectively. The transistor 10 according to the present embodiment includes the polysilicon films 51, 52, and 53 on the gate electrode 41, the source electrode 42, and the drain electrode 43, respectively. As described above, when forming the plugs 71, 72, and 73 containing W, polysilicon acts as a catalyst to decompose the material containing W (for example, WF₆). Therefore, the material of the plugs 71, 72, and 73 containing W is selectively grown on the polysilicon films 51, 52, and 53 exposed in the openings 62a, 62b, and 62c, respectively. Therefore, even if the aspect ratio of each of the openings 62a, 62b, and 62c is large, the material of the plugs 71, 72, and 73 enters the openings 62a, 62b, and 62c sufficiently, so that the plugs 71, 72, and 73 can be suitably formed. Thus, according to the transistor 10 and the method for manufacturing the same according to the present embodiment, it is possible to increase the aspect ratio of each of the openings 62a, 62b, and 62c in which the plugs 71, 72, and 73 are embedded. As a result, the number of layers of the plugs 71, 72, and 73 and the wirings 81, 82, and 83 can be reduced to suppress an increase in the number of steps for forming the plugs 71, 72, and 73, and the wirings 81, 82, and 83.

In addition, in the W film formation using polysilicon as a catalyst, HF vapor is not generated as shown in reaction formula (1) above. Therefore, it is possible to suppress the occurrence of a situation in which the flatness of the surface of the dielectric layer 62 is adversely affected. In addition, by using polysilicon as a catalyst, the material of the plugs 71, 72, and 73 is selectively deposited in the openings 62a, 62b, and 62c but hardly deposited on the dielectric layer 62 excluding the openings 62a, 62b, and 62c. This makes it unnecessary to etch back the W film.

As in the present embodiment, at least the portions of the gate electrode 41, the source electrode 42, and the drain electrode 43 that are in contact with the polysilicon films 51, 52, and 53, respectively, may contain Ni in their composition. In the forming the electrodes, the gate electrode 41, the source electrode 42, and the drain electrode 43, which contain Ni in the composition of at least the portions in contact with the polysilicon films 51, 52, and 53, may be formed. When forming the polysilicon films 51, 52, and 53, Ni in the gate electrode 41, the source electrode 42, and the drain electrode 43 acts to promote the decomposition of the material (for example, SiH₄) of the polysilicon films 51, 52, and 53. Therefore, the polysilicon films 51, 52, and 53 can be easily formed.

As in the present embodiment, at least the portions of the gate electrode 41, the source electrode 42, and the drain electrode 43 in contact with the polysilicon films 51, 52, and 53 may be made of only Ni. In the forming the electrodes, the gate electrode 41, the source electrode 42, and the drain electrode 43, in which at least the portions in contact with the polysilicon films 51, 52, and 53 are made of only Ni, may be formed. In this case, the decomposition of the material of polysilicon films 51, 52, and 53 is promoted more effectively. Therefore, the polysilicon films 51, 52, and 53 can be formed more easily.

As in the present embodiment, in the forming the polysilicon films, the polysilicon films 51, 52, and 53 may be formed at room temperature by using SiH₄ as a raw material for film formation. When SiH₄ is used as a raw material for film formation, Ni in the gate electrode 41, the source electrode 42, and the drain electrode 43 acts more effectively to further promote the decomposition of the material (SiH₄) of the polysilicon films 51, 52, and 53. Therefore, the polysilicon films 51, 52, and 53 can be easily formed at room temperature.

As in the present embodiment, the plugs 71, 72, and 73 may be made of only W. In the forming the plugs, the plugs 71, 72, and 73 made of only W may be formed. In this case, polysilicon can act as a catalyst to more suitably form the plugs 71, 72, and 73 inside the openings 62a, 62b, and 62c, respectively.

As in the present embodiment, the ratio (D/A) between the depth D and the opening width A of each of the openings 62a, 62b, and 62c may be 2 or more. In the forming the openings, the ratio (D/A) between the depth D and the opening width A of each of the openings 62a, 62b, and 62c may be 2 or more. According to the transistor 10 and the method for manufacturing the same according to the present embodiment, the plugs 71, 72, and 73 can be embedded even in the openings 62a, 62b, and 62c having such large aspect ratios.

As in the present embodiment, the gate electrode 41, the source electrode 42, and the drain electrode 43 may contain Ni in their composition, and the semiconductor stack portion 30 may have the electron supply layer 32 containing a group III nitride semiconductor and in contact with the gate electrode 41, the first high concentration n-type semiconductor region 33 containing a group III nitride semiconductor and in contact with the source electrode 42, and the second high concentration n-type semiconductor region 34 containing a group III nitride semiconductor and in contact with the drain electrode 43. An electrode containing Ni in its composition makes a Schottky contact with, for example, a group III nitride semiconductor that has a low dopant concentration or is undoped, but has a sufficiently low contact resistance with respect to a high concentration n-type group III nitride semiconductor such as high concentration n-type GaN. Therefore, according to the transistor 10 according to the present embodiment, even if the gate electrode 41, the source electrode 42, and the drain electrode 43 contain Ni in their composition, it is possible to obtain a suitable contact form between these electrodes and the semiconductor stack portion 30.

As in the present embodiment, the semiconductor stack portion 30 may include the channel layer 31 provided between the first high concentration n-type semiconductor region 33 and the second high concentration n-type semiconductor region 34 and the electron supply layer 32 having a larger bandgap than the channel layer 31. In this case, it is possible to obtain the HEMT.

### Modifications

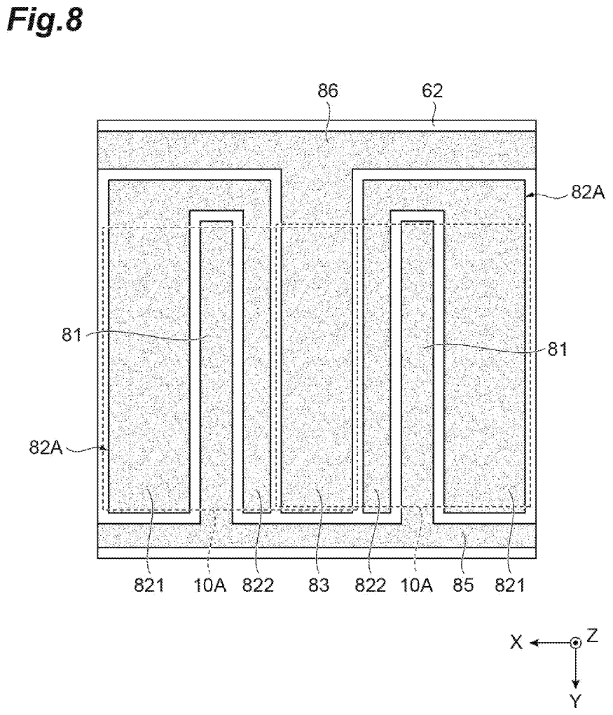

FIG. 8 is a plan view showing a wiring shape as a modification example of the embodiment described above. In addition, in FIG. 8, two transistors 10A are provided side by side in the X direction. Each transistor 10A is the same as the transistor 10 according to the embodiment described above except that the transistor 10A includes a wiring 82A instead of the wiring 82 and includes a gate wiring 85 and a drain wiring 86. In addition, the drain electrode 43 (see FIG. 1) and the wiring 83 of each transistor 10A are common.

The gate wiring 85 and the drain wiring 86 are metal films (for example, Al films) provided on the dielectric layer 62. The gate wiring 85 and the drain wiring 86 extend in the X direction across the two transistors 10A. In addition, the gate wiring 85 and the drain wiring 86 are provided at positions interposing the two transistors 10A therebetween in plan view. One end of the wiring 81 in the Y direction corresponding to the gate electrode 41 is connected to the gate wiring 85. One end of the wiring 83 in the Y direction corresponding to the drain electrode 43 is connected to the drain wiring 86. The gate wiring 85 and the drain wiring 86 may be formed simultaneously with the wirings 81, 82A, and 83 in the forming the wirings.

The wiring 82A is the same as the wiring 82 in the embodiment described above except that the planar shape of the wiring 82A is different from that of the wiring 82. The wiring 82A includes a wiring portion 821 extending along the source electrode 42 and a wiring portion 822 provided between the wiring 81 and the wiring 83 and extending in the Y direction. The wiring portion 821 and the wiring portion 822 are integrally connected near the other end of the wiring 81, so that the wiring 82A has a planar shape such as a U shape. In other words, the wiring 82A surrounds the wiring 81 from three sides.

In general, the wiring 84 provided on the back surface 22 of the substrate 20 has a reference potential (GND potential), so that the potential of the source electrode 42 becomes the reference potential. Therefore, the potential of the wirings 82 and 82A also becomes the reference potential. For example, when the transistor 10 is used in a high frequency band, it is required to reduce noise superimposed on the gate signal. By interposing the wiring 81 corresponding to the gate electrode 41 using the wiring 82A corresponding to the source electrode 42 as in this modification example, it is possible to reduce noise superimposed on the gate signal because the wiring 82A serves as a shield.

The transistor and the method for manufacturing a transistor according to the present disclosure are not limited to the embodiment described above, and various modifications can be made. For example, although the polysilicon film, the plug, and the wiring are provided on all of the gate electrode 41, the source electrode 42, and the drain electrode 43 in the above embodiment, the polysilicon film, the plug, and the wiring may also be provided on one or two electrodes of the gate electrode 41, the source electrode 42, and the drain electrode 43.

In addition, although the gate electrode 41, the source electrode 42, and the drain electrode 43 contain Ni in the above embodiment, the gate electrode 41, the source electrode 42, and the drain electrode 43 may not contain Ni as long as the polysilicon film can be formed on the gate electrode 41, the source electrode 42, and the drain electrode 43.

What is claimed is:

1. A transistor, comprising:
a semiconductor stack portion;
a source electrode and a drain electrode provided on the semiconductor stack portion and a gate electrode provided between the source electrode and the drain electrode on the semiconductor stack portion;
a first polysilicon film provided on a first electrode that is one of the gate electrode, the source electrode, and the drain electrode;
a dielectric layer that is provided on the semiconductor stack portion, covers the gate electrode, the source electrode, the drain electrode, and the first polysilicon film, and has a first opening formed on the first polysilicon film;
a first plug containing tungsten, embedded in the first opening, and in contact with the first polysilicon film; and
a first wiring provided on the dielectric layer and in contact with the first plug.

2. The transistor according to claim 1,
wherein at least a portion of the first electrode in contact with the first polysilicon film contains nickel in its composition.

3. The transistor according to claim 2,
wherein at least a portion of the first electrode in contact with the first polysilicon film is made of only nickel.

4. The transistor according to claim 1,
wherein the first plug is made of only tungsten.

5. The transistor according to claim 1,
wherein a ratio (D/A) between a depth D and an opening width A of the first opening is 2 or more.

6. The transistor according to claim 1, further comprising:
a second polysilicon film provided on a second electrode that is another one of the gate electrode, the source electrode, and the drain electrode; and
a third polysilicon film provided on a third electrode that is remaining one of the gate electrode, the source electrode, and the drain electrode,
wherein the dielectric layer further covers the second polysilicon film and the third polysilicon film and further has a second opening and a third opening formed on the second polysilicon film and the third polysilicon film, respectively, and
the transistor further includes:
a second plug containing tungsten, embedded in the second opening, and in contact with the second polysilicon film;
a third plug containing tungsten, embedded in the third opening, and in contact with the third polysilicon film; and
a second wiring and a third wiring provided on the dielectric layer and in contact with the second plug and the third plug, respectively.

7. The transistor according to claim 6,
wherein at least a portion of the second electrode in contact with the second polysilicon film and at least a portion of the third electrode in contact with the third polysilicon film contain nickel in their composition.

8. The transistor according to claim 6,
wherein the gate electrode, the source electrode, and the drain electrode contain nickel in their composition, and
the semiconductor stack portion has a semiconductor layer containing a group III nitride semiconductor and in contact with the gate electrode, a first high concentration n-type semiconductor region containing a group III nitride semiconductor and in contact with the source electrode, and a second high concentration n-type semiconductor region containing a group III nitride semiconductor and in contact with the drain electrode.

9. The transistor according to claim 8,
wherein the semiconductor stack portion includes:
a channel layer provided between the first high concentration n-type semiconductor region and the second high concentration n-type semiconductor region; and
an electron supply layer having a larger bandgap than the channel layer.

10. A method for manufacturing a transistor, comprising:
forming a source electrode, a drain electrode, and a gate electrode located between the source electrode and the drain electrode, on a semiconductor stack portion;
forming a first polysilicon film on a first electrode that is one of the gate electrode, the source electrode, and the drain electrode;
forming a dielectric layer covering the gate electrode, the source electrode, the drain electrode, and the first polysilicon film, on the semiconductor stack portion;
forming a first opening on the first polysilicon film in the dielectric layer;
forming a first plug in contact with the first polysilicon film by embedding a material containing tungsten in the first opening; and
forming a first wiring in contact with the first plug on the dielectric layer.

11. The method for manufacturing a transistor according to claim 10,
wherein, in the forming the source electrode, the drain electrode, and the gate electrode, the first electrode is formed so that at least a portion of the first electrode in contact with the first polysilicon film contains nickel in its composition.

12. The method for manufacturing a transistor according to claim 11,
wherein, in the forming the source electrode, the drain electrode, and the gate electrode, the first electrode is formed so that at least a portion of the first electrode in contact with the first polysilicon film is made of only nickel.

13. The method for manufacturing a transistor according to claim 11,
wherein, in the forming the first polysilicon film, the first polysilicon film is formed at room temperature by using SiH₄ as a raw material for film formation.

14. The method for manufacturing a transistor according to claim 10,
wherein, in the forming the first plug, the first plug made of only tungsten is formed.

15. The method for manufacturing a transistor according to claim 10,
wherein, in the forming the first opening, a ratio (D/A) between a depth D and an opening width A of the first opening is set to 2 or more.

16. The method for manufacturing a transistor according to claim 10,
wherein, in the forming the first polysilicon film, a second polysilicon film is further formed on a second electrode that is another one of the gate electrode, the source electrode, and the drain electrode, and a third polysilicon film is further formed on a third electrode that is remaining one of the gate electrode, the source electrode, and the drain electrode,
in the forming the dielectric layer, the dielectric layer further covering the second polysilicon film and the third polysilicon film is formed,
in the forming the first opening, a second opening is further formed on the second polysilicon film in the dielectric layer and a third opening is further formed on the third polysilicon film in the dielectric layer,
in the forming the first plug, a second plug in contact with the second polysilicon film and a third plug in contact with the third polysilicon film are further formed by further embedding a material containing tungsten in the second opening and the third opening, and
in the forming the first wiring, a second wiring in contact with the second plug and a third wiring in contact with the third plug are further formed on the dielectric layer.

17. The method for manufacturing a transistor according to claim 16,
wherein, in the forming the source electrode, the drain electrode, and the gate electrode, the second electrode containing nickel in a composition of at least a portion in contact with the second polysilicon film and the third electrode containing nickel in a composition of at least a portion in contact with the third polysilicon film are formed.

18. The method for manufacturing a transistor according to claim 16,
wherein the semiconductor stack portion has a semiconductor layer containing a group III nitride semiconductor, a first high concentration n-type semiconductor region containing a group III nitride semiconductor, and a second high concentration n-type semiconductor region containing a group III nitride semiconductor, and
in the forming the source electrode, the drain electrode, and the gate electrode, the gate electrode, the source electrode, and the drain electrode each containing nickel in their composition are formed, the gate electrode is brought into Schottky contact with the semiconductor layer, the source electrode is brought into contact with the first high concentration n-type semiconductor region, and the drain electrode is brought into contact with the second high concentration n-type semiconductor region.

19. The method for manufacturing a transistor according to claim 18,
wherein the semiconductor stack portion includes:
a channel layer provided between the first high concentration n-type semiconductor region and the second high concentration n-type semiconductor region; and
an electron supply layer having a larger bandgap than the channel layer.
